(19) United States
(12) Patent Application Publication
(10) Pub. No.: US 2026/0190457 A1
(43) Pub. Date: Jul. 2, 2026

(54) SEMICONDUCTOR DEVICE AND METHOD FOR FABRICATING THEREOF

(71) Applicant: NANYA TECHNOLOGY CORPORATION, New Taipei City (TW)

(72) Inventor: Yen-Ho CHU, New Taipei City (TW)

(21) Appl. No.: 19/002,912

(22) Filed: Dec. 27, 2024

(51) Int. Cl. H10D 84/83; H01L 21/02; H01L 21/308; H10D 62/832; H10D 84/01; H10D 84/85

(52) U.S. Cl. CPC H10D 84/8311; H10D 84/0151; H10D 84/856; H10P 50/691; H10D 62/832; H10P 14/24; H10P 14/2905; H10P 14/3411

(57) ABSTRACT

A method of fabricating a semiconductor device includes forming a substrate layer and a pad layer over the substrate layer; forming an isolation layer in the substrate layer and the pad layer, in which the isolation layer separates the substrate layer and the pad layer into a first substrate layer and a first pad layer over the first substrate layer, and a second substrate layer and a second pad layer over the second substrate layer; removing the second pad layer; lowering a top surface of the second substrate layer; and forming a semiconductor layer on the second substrate layer, in which a top surface of the semiconductor layer is substantially level with a top surface of the first substrate layer.

### BACKGROUND

Dynamic random-access memory (dynamic RAM or DRAM) is a type of random-access semiconductor memory that stores each bit of data in a memory cell. DRAM is known for its high speed operation, high density, and scalability. However, as the production of DRAM scales up, the manufacturing of DRAM becomes more challenging and more prone to defects. For example, the step height difference of a metal-oxide semiconductor device, such as the step height difference between a N-channel field effect transistor (NMOS) and a P-channel field effect transistor (PMOS) may be unfriendly for the subsequent processes such as the photo lithography process and the implant process. Therefore, there is a need for a credible apparatus and fabrication method for a semiconductor device.

### SUMMARY

The disclosure provides a method of fabricating a semiconductor device that includes forming a substrate layer and a pad layer over the substrate layer; forming an isolation layer in the substrate layer and the pad layer, in which the isolation layer separates the substrate layer and the pad layer into a first substrate layer and a first pad layer over the first substrate layer, and a second substrate layer and a second pad layer over the second substrate layer; removing the second pad layer; lowering a top surface of the second substrate layer; and forming a semiconductor layer on the second substrate layer, in which a top surface of the semiconductor layer is substantially level with a top surface of the first substrate layer.

In some embodiment, in which lowering the top surface of the second substrate layer includes performing an etching process using hydrogen chloride (HCl) and hydrogen (H₂).

In some embodiment, in which lowering the top surface of the second substrate layer is performed under a temperature lower than a melting point of a material of the second substrate layer.

In some embodiment, in which the temperature is in a range of approximately 930° C.±20° C.

In some embodiment, in which lowering the top surface of the second substrate layer is performed in a time period of approximately 5 seconds ±1 second.

In some embodiment, in which lowering the top surface of the second substrate layer comprises etching a vertical length of the second substrate layer by approximately 8 nm to approximately 10 nm from the top surface of the second substrate layer.

In some embodiment, in which forming the semiconductor layer on the second substrate layer is performed in a deposition rate in a range of approximately 0.1 Å/sec to approximately 0.8 Å/sec.

In some embodiment, in which forming the semiconductor layer on the second substrate layer is performed in a deposition temperature in a range of approximately 700° C.±50° C.

In some embodiment, in which forming the semiconductor layer on the second substrate layer is performed in a deposition pressure in a range of approximately 5 mTorr to approximately 30 mTorr.

In some embodiment, in which forming the semiconductor layer on the second substrate layer comprises a silicon (Si) precursor, in which the Si precursor is dichlorosilane (DCS; SiH₂Cl₂) or silane (SiH₄), and a germanium (Ge) precursor, in which the Ge precursor is germanium tetrafluoride (GeF₄).

The disclosure provides a semiconductor device that includes a substrate layer having a first region and a second region; an isolation layer between the first region and the second region of the substrate layer; a first transistor over the first region of the substrate layer and comprising: a first portion of the substrate layer; and a first gate structure over the first portion of the substrate layer; and a second transistor over the second region of the substrate layer and includes a second portion of the substrate layer; a semiconductor layer over the second portion of the substrate layer, in which a top surface of the semiconductor layer is substantially level with a top surface of the first portion of the substrate layer; and a second gate structure over the semiconductor layer.

In some embodiment, in which a top surface of the second portion of the substrate layer is lower than the top surface of the first portion of the substrate layer.

In some embodiment, in which the semiconductor layer has a vertical length of approximately 8 nm to approximately 10 nm.

In some embodiment, in which the isolation layer has a stepped top surface profile.

In some embodiment, in which the isolation layer includes a first portion closer to the first region of the substrate layer, in which a top surface of the first portion of the isolation layer is substantially level with the top surface of the first portion of the substrate layer.

In some embodiment, in which the isolation layer further comprises a second portion closer to the second region of the substrate layer, in which a top surface of the second portion of the isolation layer is at a lower vertical level than the top surface of the second portion of the substrate layer.

In some embodiment, in which the semiconductor layer and the first portion of the substrate layer are made of different semiconductor materials.

In some embodiment, in which the semiconductor layer is made of silicon-germanium (SiGe) and the substrate layer is made of silicon (Si).

In some embodiment, in which the first transistor comprises first source/drain regions in the first portion of the substrate layer and on opposite sides of the first gate structure, and the second transistor comprises second source/drain regions in the semiconductor layer and on opposite sides of the second gate structure, in which the first source/drain regions include N-type dopants and the second source/drain regions include P-type dopants.

In some embodiment, in which the second source/drain regions further extend to the second portion of the substrate layer.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic view of a semiconductor device, in accordance with some embodiments of the present disclosure.

FIG. 2 is a schematic view of a memory cell, in accordance with some embodiments of the present disclosure.

FIG. 3 is a flow chart of a method of fabricating a semiconductor device, in accordance with some embodiments of the present disclosure.

FIGS. 4 to 15 illustrate a method of fabricating a semiconductor device, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

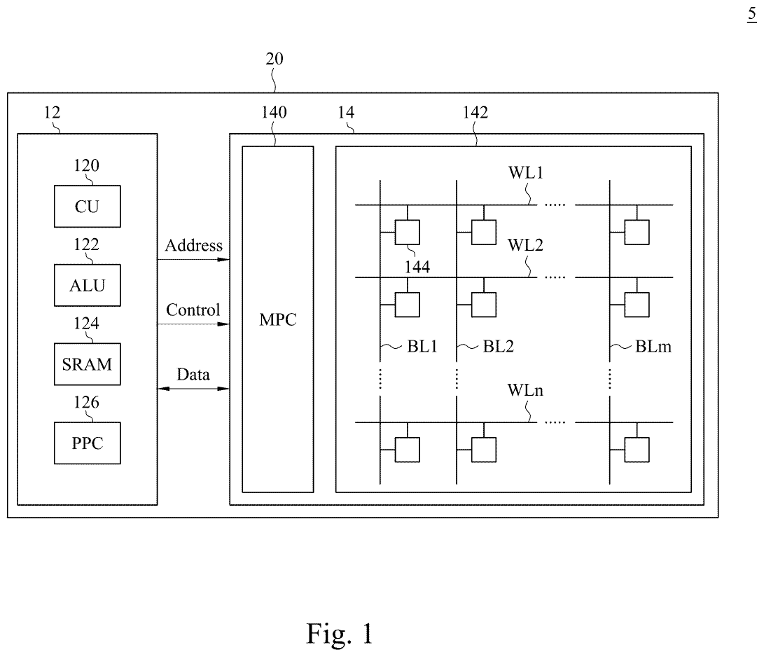

FIG. 1 is a schematic view of a semiconductor device, in accordance with some embodiments of the present disclosure. Referring to FIG. 1, the semiconductor system 5 is a system on a chip (SOC) device. The semiconductor system 5 is made of different semiconducting materials on a single semiconductor substrate 20. Moreover, the semiconductor system 5 is designed to undergo a semiconductor package process other than, for example, a system in package (SiP) process for integrating two independent dies.

The semiconductor system 5 includes a processing unit 12 and a semiconductor memory 14. The semiconductor memory 14 may be referred to as a first semiconductor memory, if appropriate.

The processing unit 12 functions to follow an instruction cycle. The instruction cycle is followed by the processing unit 12 to process instructions from boot-up until, for example, a computer has shut down. The instruction cycle is composed of three main stages: a fetch stage, a decode stage, and an execute stage.

In some embodiments, the processing unit 12 includes standard processors, such as a field programmable gate array (FPGA), a central processing unit (CPU), a graphic processing unit (GPU), an application specific integrated circuit (ASIC), an application-specific standard part (ASSP), and a micro control unit (MCU). However, the present disclosure is not limited thereto. In some embodiments, the processing unit 12 may include another suitable processing device.

The processing unit 12 includes a logic circuit having a control unit (CU) 120 and an arithmetic logic unit (ALU) 122, a static random-access memory (SRAM) 124, and a processing peripheral circuit (PPC) 126.

The CU 120 functions to direct operations within the processing unit 12. In some embodiments, the CU 120 directs the computer's logic unit, memory, and input and output devices in response to instructions received from a program.

The ALU 122, coupled to the CU 120, functions to perform both bitwise and mathematical operations on binary numbers. The ALU 122 is the last component to perform calculations in the processing unit 12. The ALU 122 performs operations on input data based on operands and code received. After the information has been processed by the ALU 122, the processed information is sent to the semiconductor memory 14.

The SRAM 124, coupled to the CU 120 and the ALU 122, functions to serve as a cache of the processing unit 12, in which the SRAM 124 is a first-level cache. The SRAM 124 may be referred to as a second semiconductor memory, if appropriate.

The PPC 126 functions as a communication interface for communication between the logic circuit of the processing unit 12 and electrical components, such as the semiconductor memory 14, external to the processing unit 12. In structure, for example, the logic circuit is not directly coupled to the semiconductor memory 14. Rather, the logic circuit is directly coupled to the PPC 126, and then indirectly coupled to the semiconductor memory 14 via the PPC 126.

The semiconductor memory 14, coupled to the processing unit 12, functions to store instructions required in the instruction cycle and functions to serve as a main memory of the processing unit 12.

In some embodiments, the semiconductor memory 14 includes a volatile memory or a non-volatile memory. The non-volatile memory includes a magnetoresistive random access memory (MRAM), a resistive random-access memory (ReRAM), a conductive bridge memory (CBM), a phase-change memory (PCM), a nano-tube rain (NRAM), a ferroelectric field-effect transistor (FeFET) memory, a 3D Xpoint (3DXP) memory, or a flash memory. The volatile memory includes a dynamic random-access memory (DRAM).

The semiconductor memory 14 includes a memory cell array 142 and a memory peripheral circuit (MPC) 140. The memory cell array 142 includes a plurality of word lines WL1 to WLn, a plurality of bit lines BL1 to BLm, and a plurality of memory cells 144, in which n and in are positive integers and are greater than 1. The memory cells 144 are arranged in columns and rows. The memory cell 144 is disposed at each intersection of a word line with a bit line, and functions to store data in a digital binary form. The memory cell 144, for example, includes a storage device for storing data, and a memory transistor for performing cell selection. In an embodiment where the semiconductor memory 14 is a DRAM, the storage device includes a capacitor. In another embodiment where the semiconductor memory 14 is an MRAM, the storage device includes a magnetic tunneling junction (MJT) transistor.

The MPC 140 functions as a communication interface for communication between the memory cell array 142 and electrical components, such as the processing unit 12, external to the semiconductor memory 14. In structure, for example, the memory cell array 142 is not directly coupled to the processing unit 12. Rather, the memory cell array 142 is directly coupled to the MPC 140, and then indirectly coupled to the processing unit 12 via the MPC 140.

In addition, the MPC 140 functions to control the memory cell array 142. The MPC 140 includes, for example, a row decoder, a column decoder, an address buffer, an input/output (I/O) buffer, a clock generator, a direct-current (DC) generator and a sense amplifier (S/A).

In operation, the processing unit 12 generates and provides a data signal Data, an address signal ADD, and a memory control signal Control to the MPC 140 to access the memory cell array 142. In some embodiments, the memory control signal Control includes a command signal. However, the present disclosure is not limited thereto. In some embodiments, the memory control signal Control includes other suitable signals.

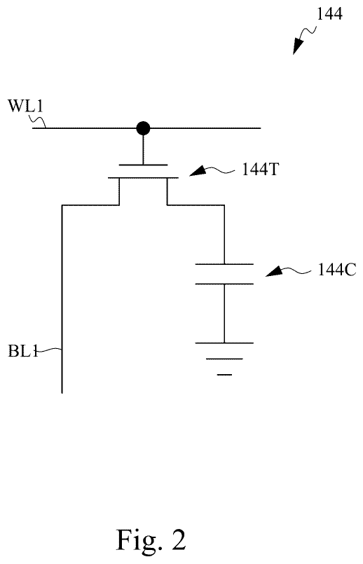

FIG. 2 is a schematic view of a memory cell, in accordance with some embodiments of the present disclosure. Specifically, FIG. 2 is a close-up view of FIG. 1. In some embodiments, a memory cell 144 includes an access transistor 144T and a storage capacitor 144C electrically connected to the access transistor 144T.

In some embodiments, the access transistor 144T is an NMOS transistor, and is configured to control the channel to the memory cell 144 by opening or closing the gate of the access transistor 144T. In some embodiments, the storage capacitor 144C is configured to store information according to the state of electrical charges stored therein. The storage capacitor 144C in an empty state, that is, no charge, is denoted a logic value of 0. The storage capacitor 144C in a fully-charged state is denoted a logic value of 1. The memory cell 144 stores a bit of data by means of the two extreme states of charges stored in the storage capacitor 144C.

In some embodiments, a word line WL1 connected to the access transistor 144T is used to control the gate of the access transistor 144T by applying a voltage to the gate of the access transistor 144T. In some embodiments, a bit line BL1 is arranged perpendicular to the word line WL1 and is also connected to the access transistor 144T. When the gate of the access transistor 144T is turned on, the access transistor 144T connects the storage capacitor 144C to the bit line BL1 such that the logic value stored in the storage capacitor 144C will be read on the bit line BL1.

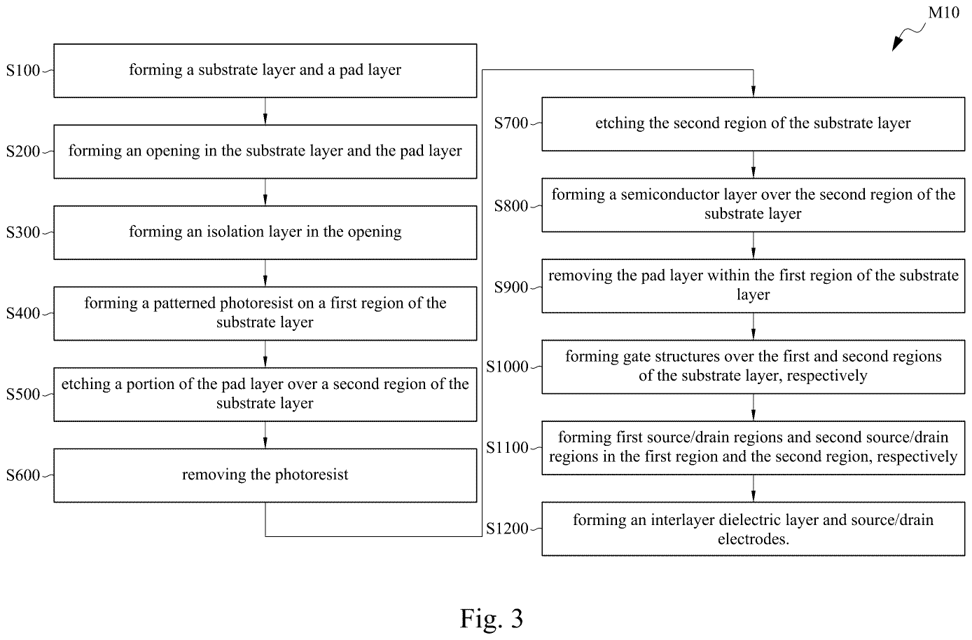

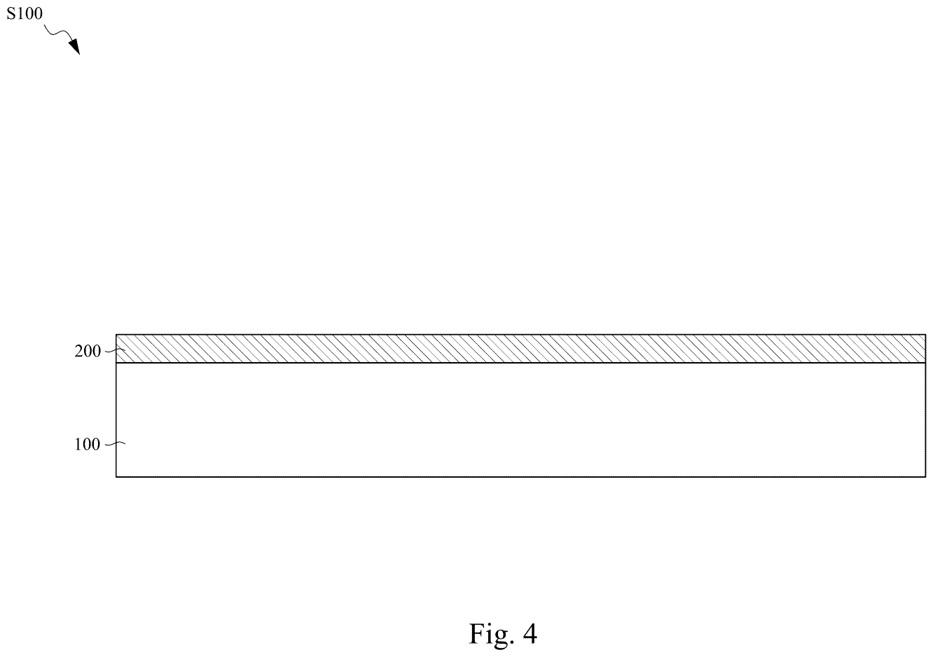

FIG. 3 is a flow chart of a method of fabricating a semiconductor device, in accordance with some embodiments of the present disclosure. FIG. 4 to FIG. 15 illustrate a method of fabricating a semiconductor device, in accordance with some embodiments of the present disclosure.

The semiconductor device and the fabricating method M10 will be discussed in conjunction with reference to FIG. 4 to FIG. 15. As illustrated in FIG. 3, a fabricating method M10 may include the following operations S100, S200, S300, S400, S500, S600, S700, S800, S900, S1000, S1100 and S1200.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

The method M10 starts from operation S100 by forming a substrate layer and a pad layer. Referring to FIG. 4, the substrate layer 100 and pad layer 200 are formed.

In some embodiments, the substrate layer 100 is made of silicon (Si). In some embodiments, the substrate layer 100 is configured to act as a base structure for supporting a N-type metal oxide semiconductor (NMOS) device and/or a P-type metal oxide semiconductor (PMOS) device formed in the following processes.

In some embodiments, the pad layer 200 is formed on the substrate layer 100. In some embodiments, the pad layer 200 is made of dielectric material. In some embodiments, the pad layer 200 is a pad oxide. In some embodiments, the pad layer 200 is made of silicon oxide (SiO₂).

In some embodiments, the pad layer 200 is formed using a thermal oxidation process. In some embodiments, the pad layer 200 can be formed by a chemical vapor deposition (CVD) method. In some embodiments, the vertical thickness of the pad layer 200 thickness is about 10 nm to 500 nm.

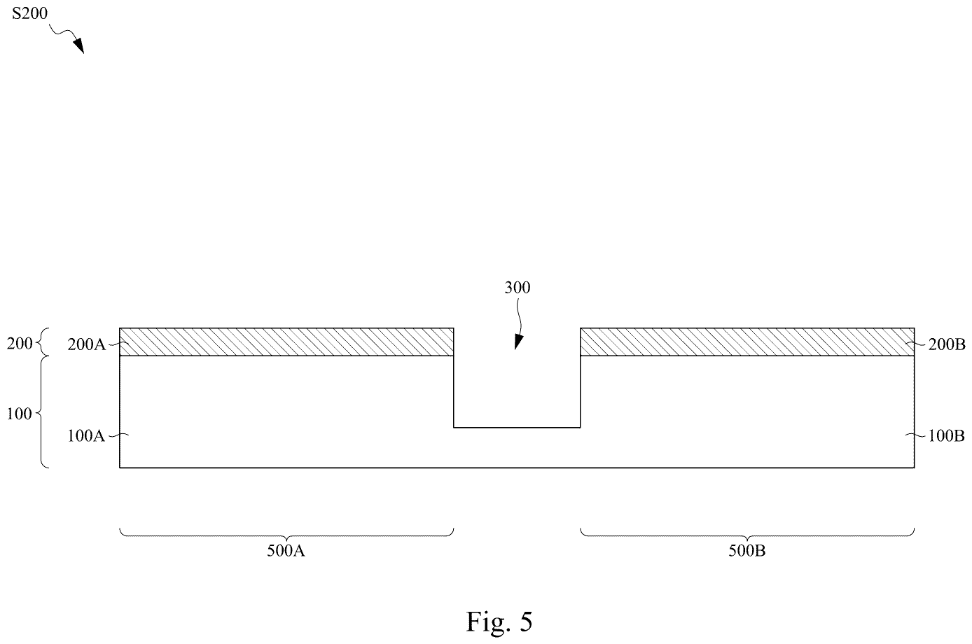

The method M10 proceeds to operation S200 by forming an opening in the substrate layer and the pad layer. Referring to FIG. 5, the opening 300 is formed in the substrate layer 100 and the pad layer 200 to separate the substrate layer 100 and the pad layer 200 into two regions—the first region 500A and the second region 500B.

In some embodiments, a patterned mask layer (not shown) may be formed on top of the pad layer 200 of the first region 500A and the second region 500B. The patterned mask layer is configured to act as an etch protector for the underneath pad layer 200 over the first region 500A and the second region 500B in the subsequent etching process. In some embodiments, the patterned mask layer may not cover the center region of the pad layer 200.

Subsequently, an etching process may be performed to etch the center region of the pad layer 200 and etch a part of the substrate layer 100 through the patterned mask layer. As a result, the opening 300 is formed, which separates the substrate layer 100 and the pad layer 200 into two regions—the first region 500A and the second region 500B.

As a result of the formation of the opening 300, the first region 500A includes the first substrate layer 100A and the first pad layer 200A. On the other side, the second region 500B includes the second substrate layer 100B and the second pad layer 200B.

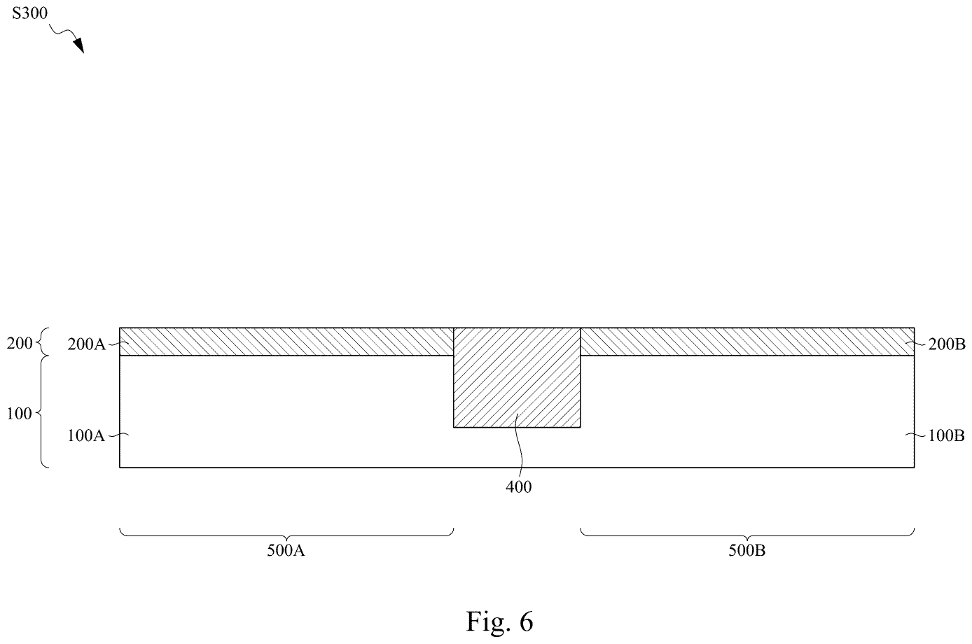

The method M10 proceeds to operation S300 by forming an isolation layer in the opening. Referring to FIG. 6, the isolation layer 400 is formed in the opening 300.

In some embodiments, the isolation layer 400 is made of dielectric material. In some embodiments, the isolation layer 400 is configured to provide an electrical isolation between the first substrate layer 100A and the second substrate layer 100B. In some embodiments, the isolation layer 400 is a shallow trench isolation (STI) structure.

The isolation layer 400 may be deposited by using CVD, PECVD, ALD, PVD, LPCVD, FCVD, or other suitable deposition processes. A chemical mechanical polishing (CMP) process may be used for the planarization process to remove the excess portions of the isolation layer 400 and to level the isolation layer 400 with the pad layer 200.

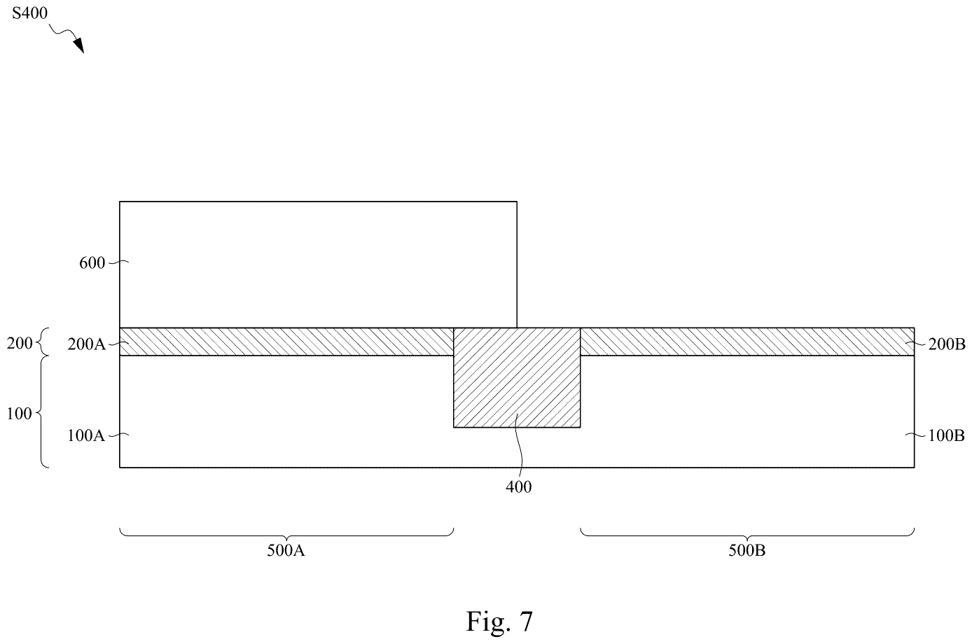

The method M10 proceeds to operation S400 by forming a patterned photoresist on a first region of the substrate layer. Referring to FIG. 7, a patterned photoresist 600 is formed over the first region 500A of the substrate layer 100. A photoresist material layer (not shown) can be formed over the first region 500A using suitable deposition processes, such as spin coating. Then the photoresist material layer is exposed to a light source through a photomask (not shown) that has a specific pattern. In some embodiments, the area of the photoresist material layer becomes soluble when exposed to light. As a result, the exposed area of the photoresist material layer can be washed away to define the patterned photoresist 600.

In some embodiments, the patterned photoresist 600 may be formed on top of the first pad layer 200A. In some embodiments, the patterned photoresist 600 may also cover a part of the isolation layer 400, while leaving another part of the isolation layer 400 exposed. In some embodiments, the part of the isolation layer 400 covered by the patterned photoresist 600 may be closer to the first region 500A than to the second region 500B.

The patterned photoresist 600 is configured to act as an etch protector for the underneath first pad layer 200A over the first substrate layer 100A in the subsequent etching process. The patterned photoresist 600 may also be configured to act as an etch protector for the underneath partial isolation layer 400 in the subsequent etching process.

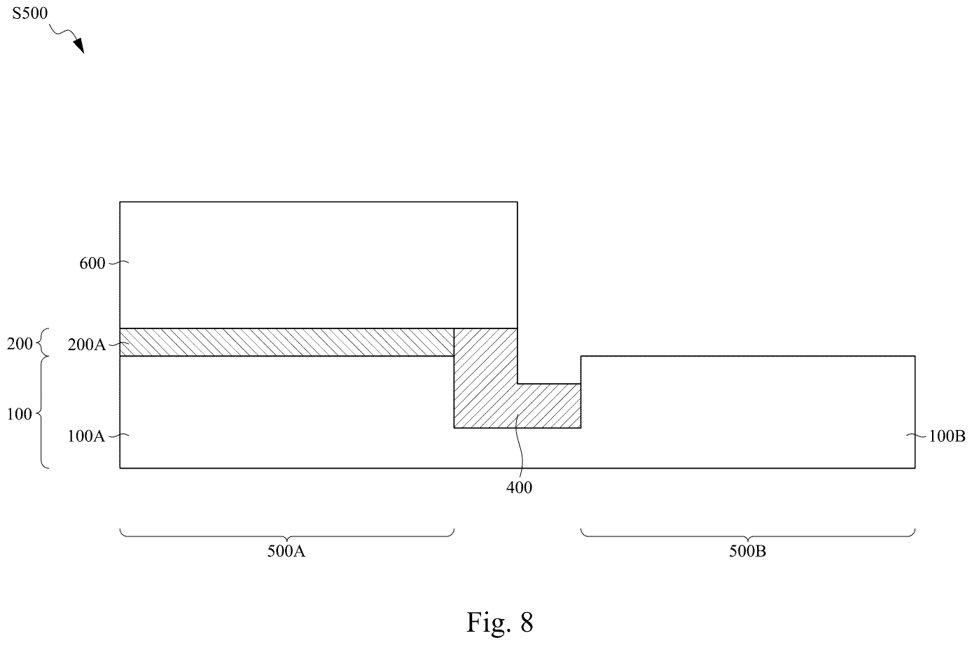

The method M10 proceeds to operation S500 by etching a portion of the pad layer over a second region of the substrate. Referring to FIG. 8, an etching process is performed on the second region 500B of the substrate layer 100 through the photoresist 600. In some embodiments, the second pad layer 200B is etched through the photoresist 600, such that the top surface of the second substrate layer 100B is exposed.

In some embodiments, because the isolation layer 400 and the second pad layer 200B may include a same material, such as silicon oxide, the part of the isolation layer 400 not covered by the photoresist 600 is partially etched through the photoresist 600. As a result, once the etching process is complete, the isolation layer 400 may include a stepped top surface profile.

In some embodiments, the second substrate layer 100B may have a higher etch resistance to the etching process than the second pad layer 200B and the isolation layer 400. Accordingly, once the second pad layer 200B is removed, the exposed second substrate layer 100B may act as an etch stop layer to the etching process, while the etching process may continuously etch the isolation layer 400. As a result, the top surface of the isolation layer 400 after etching may be at a lower vertical level than the exposed second substrate layer 100B after the etching process. In some embodiments, the etching process may stop when the second substrate layer 100B is exposed. In some embodiments, the etching process may be a dry or wet etch process.

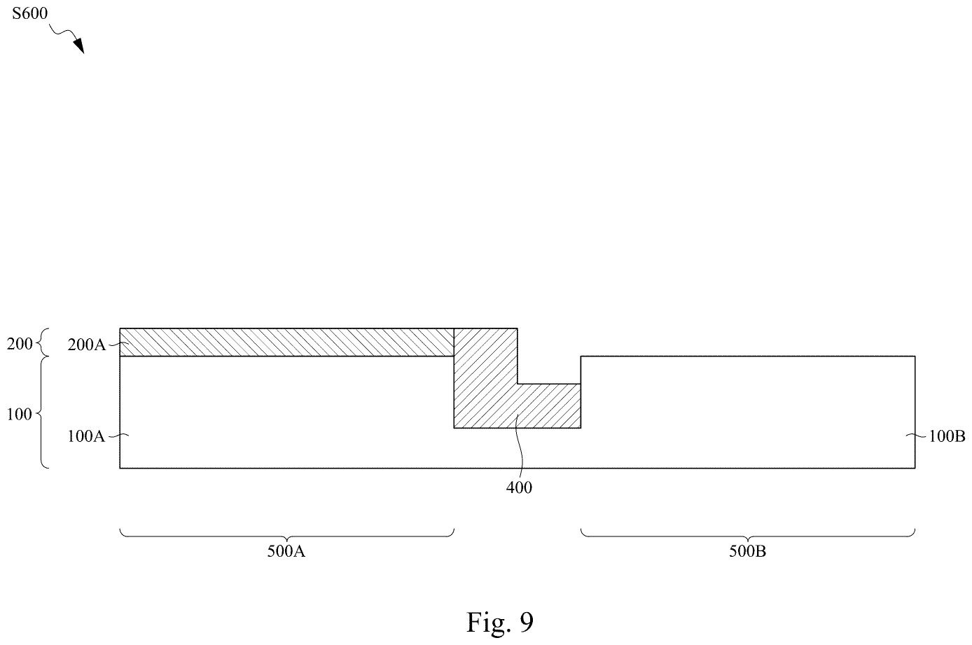

The method M10 proceeds to operation S600 by removing the photoresist. Referring to FIG. 9, the photoresist 600 is removed after the etching process. In some embodiments, the removal of the photoresist 600 includes a liquid resist stripper (not shown) that chemically alters the photoresist 600 so that the photoresist 600 no longer adheres to the first pad layer 200A or the isolation layer 400. In some embodiments, the removal of the photoresist 600 exposes the first pad layer 200A and the un-etched part of the isolation layer 400.

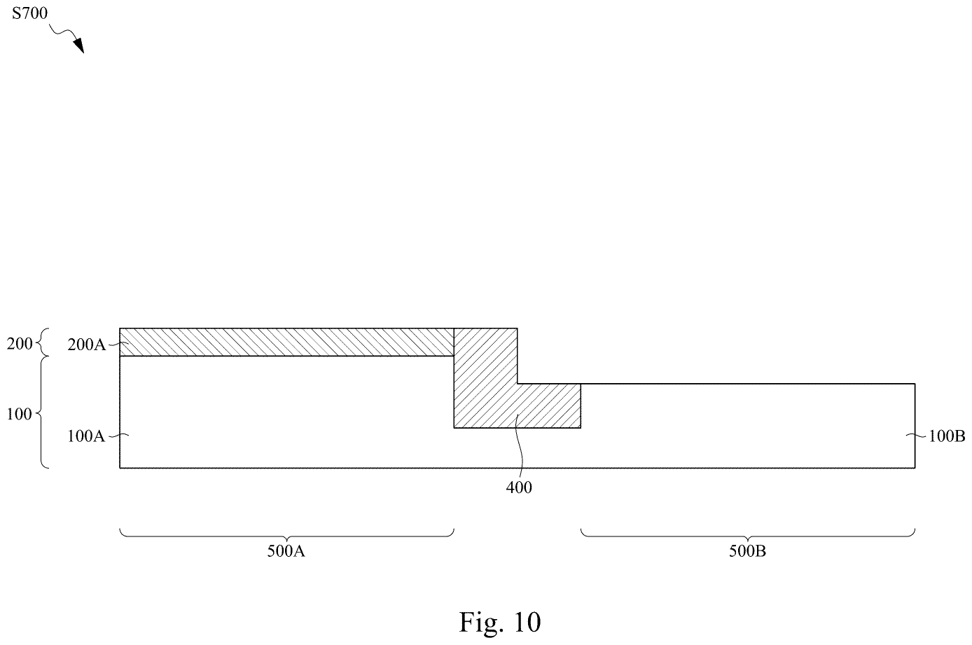

The method M10 proceeds to operation S700 by etching the second region of the substrate layer. Referring to FIG. 10, the second substrate layer 100B is etched. In some embodiments, because the first substrate layer 100A is protected by the first pad layer 200A during the etching process, the top surface of the second substrate layer 100B is at a level that is lower than the top surface of the first substrate layer 100A when the etching process is complete.

In some embodiments, the etching process may be a wet etch process. In some embodiments, the etching process may include certain etchants, such as hydrogen chloride (HCl) and hydrogen (H₂), that etch the second substrate layer 100B. In some embodiments, the first pad layer 200A and the isolation layer 400 may include a higher etch resistance to the etching process for etching the second substrate layer 100B, such that the first pad layer 200A and the isolation layer 400 may keep substantially intact once the etching process is complete.

In some embodiments, the etching process may be performed in an etching temperature lower than a melting point of a material of the second substrate layer 100B. In some embodiments, the etching process may be performed in an etching temperature range of approximately 930° C.±20° C. In some embodiments, the etching temperature range of approximately 930° C.±20° C. facilitates the second substrate layer 100B to have a smooth top surface after the etching process. In some embodiments, the temperature of approximately 930° C.±20° C. has not reached the melting point of the material of the second substrate layer 100B (e.g., silicon), thus avoids the second substrate layer 100B from going through an unintended physical change of its shape.

In some embodiments, the etching process may be performed in a time period of approximately 5 seconds ±1 second. In some embodiments, the etching process may etch a vertical length of approximately 8 nm to approximately 10 nm from the top surface of the second substrate layer 100B. In some embodiments, the top surface of the second substrate layer 100B after etching and the top surface of the etched part of the isolation layer 400 may be at a substantially same level.

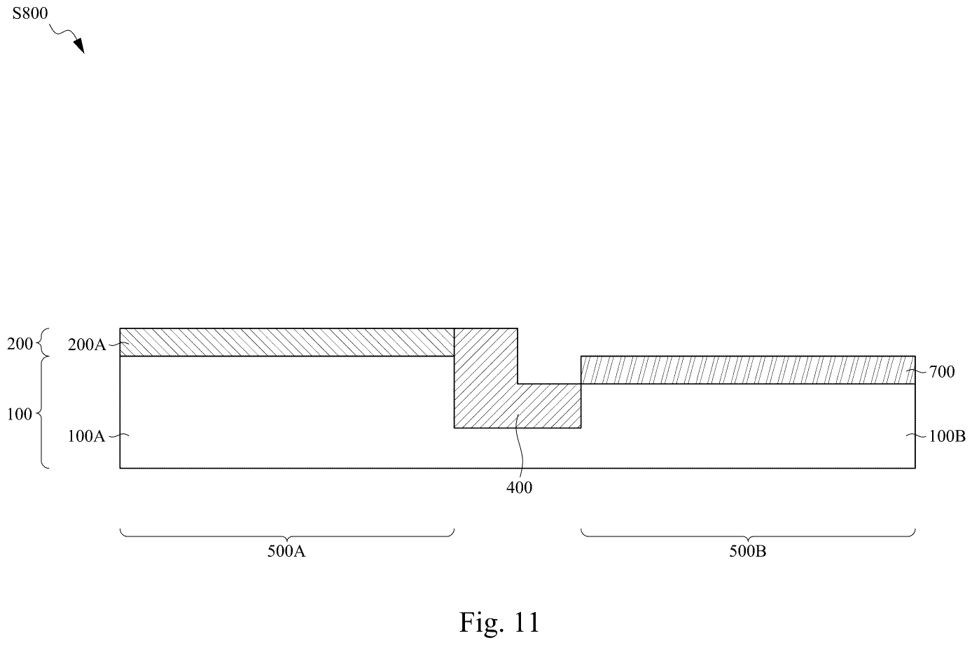

The method M10 proceeds to operation S800 by forming a semiconductor layer over the second region of the substrate layer. Referring to FIG. 11, a semiconductor layer 700 is formed on the second substrate layer 100B.

In some embodiments, the semiconductor layer 700 may be made of a semiconductor material that is different from a material of the substrate layer 100 (e.g., silicon). In some embodiments, the semiconductor layer 700 may be made of silicon-germanium (SiGe). In some embodiments, the semiconductor layer 700 may be configured to act as a channel layer of a semiconductor device formed in the subsequent processes.

In some embodiments, the semiconductor layer 700 may be deposited on the second substrate layer 100B. The semiconductor layer 700 may be deposited by using CVD, PECVD, ALD, PVD, LPCVD, FCVD, or other suitable deposition processes.

In some embodiments, the semiconductor layer 700 has a low deposition rate to facilitate growing a smooth top surface. In some embodiments, the deposition rate of the semiconductor layer 700 is in a range of approximately 0.1 Å/sec to approximately 0.8 Å/sec. Moreover, the low deposition rate may be beneficial to control the thickness of the semiconductor layer 700.

In some embodiments, the semiconductor layer 700 has a low deposition temperature to facilitate growing a smooth top surface. In some embodiments, the deposition temperature of the semiconductor layer 700 is in a range of approximately 700° C.±50° C. In some embodiments, the deposition pressure of the semiconductor layer 700 is in a range of approximately 5 mTorr to approximately 30 mTorr.

In some embodiments, the deposition of the semiconductor layer 700 may use a silicon (Si) precursor, a germanium (Ge) precursor, and HCl. In some embodiments, the Si precursor can be dichlorosilane (DCS; SiH₂Cl₂) or silane (SiH₄). In some embodiments, the Si precursor may have a flow rate in a range of approximately 100 to 180 standard cubic centimeters per minute (sccm).

In some embodiments, the Ge precursor can be germanium tetrafluoride (GeF₄) in the gas form. In some embodiments, the Ge precursor may have a flow rate in a range of approximately 10 to 90 sccm. In some embodiments, the HCl may have a flow rate in a range of approximately 50 to 150 sccm.

In some embodiments, the semiconductor layer 700 may replace the part of the second substrate layer 100B being etched in operation S700. In some embodiments, the semiconductor layer 700 has a vertical length that is substantially the same as the part of the second substrate layer 100B being etched in operation S700. In some embodiments, the third semiconductor layer 700 has a vertical length of approximately 8 nm to approximately 10 nm.

In some embodiments, the top surface of the semiconductor layer 700 is at a substantially same vertical level as the top surface of the first substrate layer 100A. In some embodiments, the top surface of the semiconductor layer 700 may be substantially flat, or smooth.

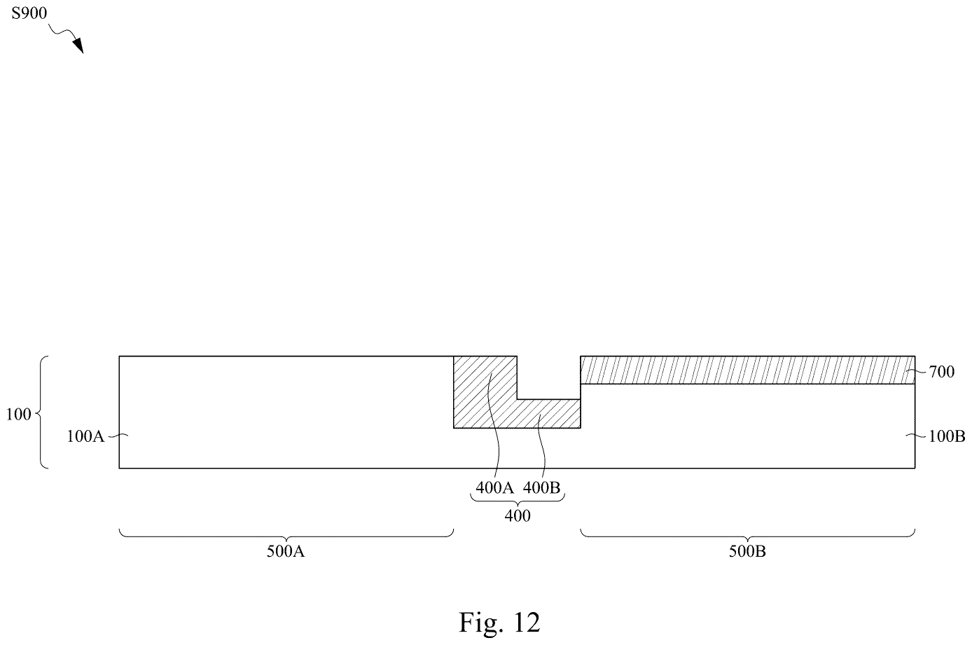

The method M10 proceeds to operation S900 by removing the pad layer within the first region of the substrate layer. Referring to FIG. 12, the first pad layer 200A is removed using suitable etching process. In some embodiments, because the isolation layer 400 and the first pad layer 200A may be made from a same material, such as oxide, the isolation layer 400 may also be etched during the etching process.

After the etching process is complete, the isolation layer 400 may include a first portion 400A and a second portion 400B in the first substrate layer 100A and the second substrate layer 100B, respectively. In some embodiments, the first portion 400A may be thicker than the second portion 400B. In some embodiments, the bottom surface of the first portion 400A may be substantially level with the bottom surface of the second portion 400B, while the top surface of the first portion 400A may be higher than the top surface of the second portion 400B. In some embodiments, the top surface of the first portion 400A of the isolation layer 400 may be substantially level with the top surface of the first substrate layer 100A, while the top surface of the second portion 400B of the isolation layer 400 may be lower than the top surface of the second substrate layer 100B.

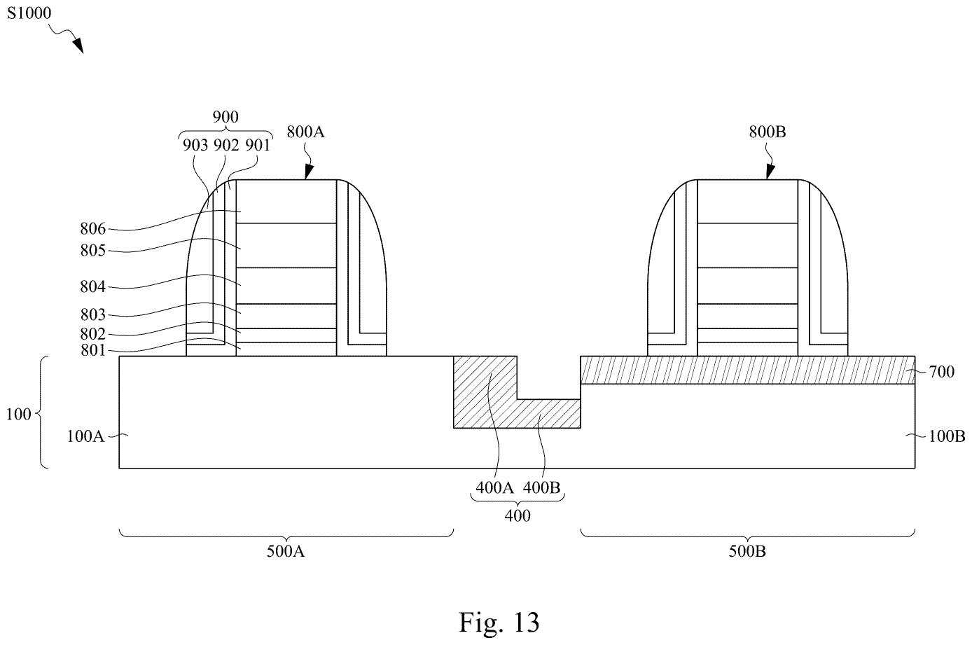

The method M10 proceeds to operation S1000 by forming gate structures over the first and second regions of the substrate layer, respectively. Referring to FIG. 13, gate structures 800A and 800B are formed over the first region 500A and the second region 500B of the substrate layer 100, respectively. Specifically, the gate structure 800A is formed in contact with the top surface of the first substrate layer 100A, and the gate structure 800B is formed in contact with the top surface of the semiconductor layer 700.

In some embodiments, the gate structures 800A and 800B each may include a gate dielectric layer 801, a high-k dielectric layer 802, a first conductive layer 803, a second conductive layer 804, a third conductive layer 805, and a dielectric capping layer 806.

The gate dielectric layer 801 may be deposited over the first substrate layer 100A and the semiconductor layer 700. In some embodiments, the gate dielectric layer 801 may be made with a dielectric material. In some embodiments, the gate dielectric layer 801 may be made with an oxide. In some embodiments, the gate dielectric layer 801 may include silicon oxide (SiO₂) or aluminum oxide (Al₂O₃).

In some embodiments, the gate dielectric layer 801 is configured to electrically separate the first substrate layer 100A and/or the semiconductor layer 700 with the conductive structure in the gate structures 800A and 800B that will be formed in the subsequent process. The gate dielectric layer 801 may be deposited by using CVD, PECVD, ALD, PVD, LPCVD, FCVD, or other suitable deposition processes.

The high-k dielectric layer 802 may be deposited on the gate dielectric layer 801. In some embodiments, the high-k dielectric layer 802 may be made with a dielectric material. In some embodiments, the high-k dielectric layer 802 may be made with a dielectric material having a high dielectric constant (high-k), such as Zirconia dioxide (ZrO₂), Hafnium Dioxide (HfO₂), or the like.

In some embodiments, similar to the gate dielectric layer 801, the high-k dielectric layer 802 is configured to electrically separate the first substrate layer 100A and/or the semiconductor layer 700 with the conductive structure in the gate structures 800A and 800B that will be formed in the subsequent process. The high-k dielectric layer 802 may be deposited by using CVD, PECVD, ALD, PVD, LPCVD, FCVD, or other suitable deposition processes.

After the high-k dielectric layer 802 is formed, the first conductive layer 803, the second conductive layer 804, and the third conductive layer 805 may be sequentially deposited over the high-k dielectric layer 802.

In some embodiments, the first conductive layer 803, the second conductive layer 804, and the third conductive layer 805 may be made with conductive material. In some embodiments, the first conductive layer 803, the second conductive layer 804, and the third conductive layer 805 may be made with metal. In some embodiments, the first conductive layer 803 may be made with titanium nitride (TiN). In some embodiments, the second conductive layer 804 may be made with polysilicon. In some embodiments, the third conductive layer 805 may be made with tungsten (W).

In some embodiments, the first conductive layer 803, the second conductive layer 804, and the third conductive layer 805 may be the gate electrode, which can electrically connect to the first substrate layer 100A and/or the second substrate layer 100B with the semiconductor layer 700. The first conductive layer 803, the second conductive layer 804, and the third conductive layer 805 may be deposited by using CVD, PECVD, ALD, PVD, LPCVD, FCVD, or other suitable deposition processes.

The dielectric capping layer 806 may be deposited over the third conductive layer 805. In some embodiments, the dielectric capping layer 806 may be made with a dielectric material. In some embodiments, the gate dielectric layer 801 may be made with silicon nitride (SiN).

The dielectric capping layer 806 may be deposited by using CVD, PECVD, ALD, PVD, LPCVD, FCVD, or other suitable deposition processes.

Next, gate spacers 900 are formed along the sidewalls of the gate structures 800A and 800B, respectively. In some embodiments, the gate spacer 900 may include a first gate spacer layer 901, a second gate spacer layer 902 over the first gate spacer layer 901, and a third gate spacer layer 903 over the second gate spacer layer 902. In some embodiments, the gate spacer 900 is made with dielectric material. In some embodiments, the first gate spacer layer 901 is made with silicon nitride (SiN). In some embodiments, the second gate spacer layer 902 is made with silicon oxide (SiO). In some embodiments, the third gate spacer layer 903 is made with silicon nitride (SiN).

In some embodiments, the gate spacers 900 are configured to laterally offset the gate structures 800A and 800B from their corresponding source/drain regions.

Each of the first gate spacer layer 901, second gate spacer layer 902, and third gate spacer layer 903 may be deposited by using CVD, PECVD, ALD, PVD, LPCVD, FCVD, or other suitable deposition processes. In some embodiments, the first gate spacer layer 901, second gate spacer layer 902, and third gate spacer layer 903 may be deposited in a conformal manner. Subsequently, an etching process may be performed to remove the horizontal portions of the gate spacers 900, leaving only the vertical portions of the gate spacers 900 along the sidewalls of the gate structures 800A and 800B, respectively.

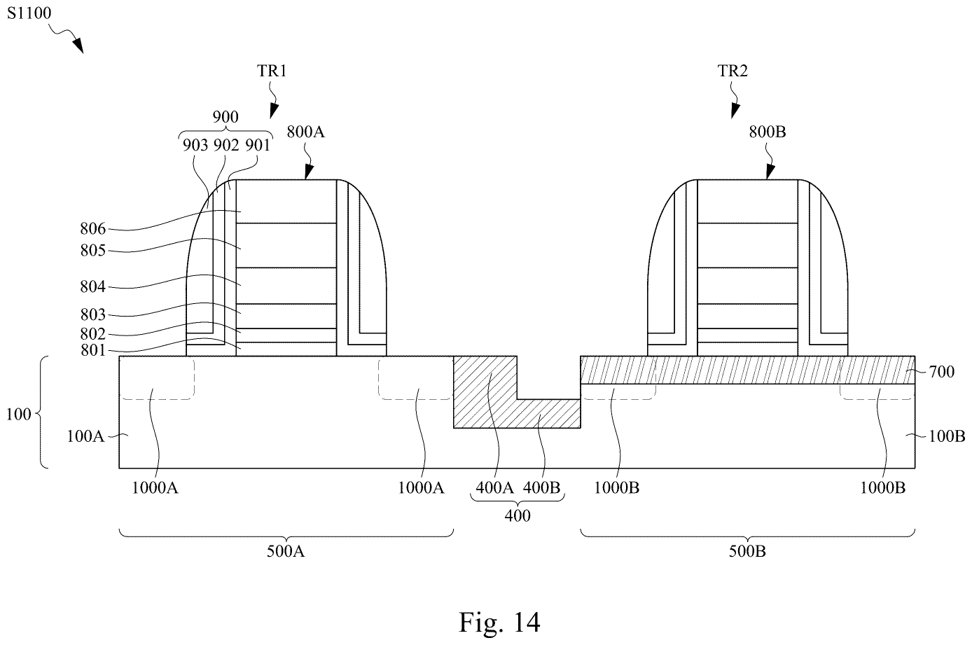

The method M10 proceeds to operation S1100 by forming first source/drain regions and second source/drain regions in the first region and the second region, respectively. Referring to FIG. 14, the first source/drain regions 1000A and the second source/drain regions 1000B are formed in the first region 500A and the second region 500B, respectively.

Specifically, the first source/drain regions 1000A are formed in the first substrate layer 100A and on opposite sides of the gate structure 800A. On the other hand, the second source/drain regions 1000B are formed in the semiconductor layer 700 and on opposite sides of the gate structure 800B.

In some embodiments, the source/drain regions 1000A and 1000B are formed by one or more ion implantation processes. In some embodiments, the source/drain regions 1000A and 1000B are implanted with certain species that modify the film conductivity type.

In some embodiments, the first substrate layer 100A may be implanted with N-type dopants. In some embodiments, the first substrate layer 100A may be implanted with phosphorus (P) and/or arsenic (As).

In some embodiments, the semiconductor layer 700 may be implanted with P-type dopants. In some embodiments, the semiconductor layer 700 and/or the second substrate layer 100B may be implanted boron (B), gallium (Ga) and/or indium (In).

In some embodiments, the implantation of P-type dopants may be performed to an upper portion of the second substrate layer 100B as well. In some embodiments, the upper portion of the second substrate layer 100B may have a higher concentration of P-type dopants such as boron (B), gallium (Ga) and/or indium (In) than the bottom portion of the second substrate layer 100B. Therefore, in some embodiments, the source/drain regions 1000B may be formed in the semiconductor layer 700 and may extend to an upper portion of the second substrate layer 100B.

After the formation of the source/drain regions 1000A and 1000B, a first semiconductor device TR1 and a second transistor device TR2 are formed, in which the first semiconductor device TR1 is formed over the first region 500A of the substrate layer 100, and the second semiconductor device TR2 is formed over the second region 500B of the substrate layer 100.

With respect to the first semiconductor device TR1, the first semiconductor device TR1 includes a first substrate layer 100A (e.g., channel layer), a gate structure 800A over the first substrate layer 100A, and source/drain regions 1000A on opposite sides of the gate structure 800A.

With respect to the second semiconductor device TR2, the second semiconductor device TR2 includes a semiconductor layer 700 (e.g., channel layer), a gate structure 800B over the semiconductor layer 700, and source/drain regions 1000B on opposite sides of the gate structure 800B.

In some embodiments, the first semiconductor device TR1 may be a N-type device, such as a NMOS device. On the other hand, the second semiconductor device TR2 may be a P-type device, such as a PMOS device.

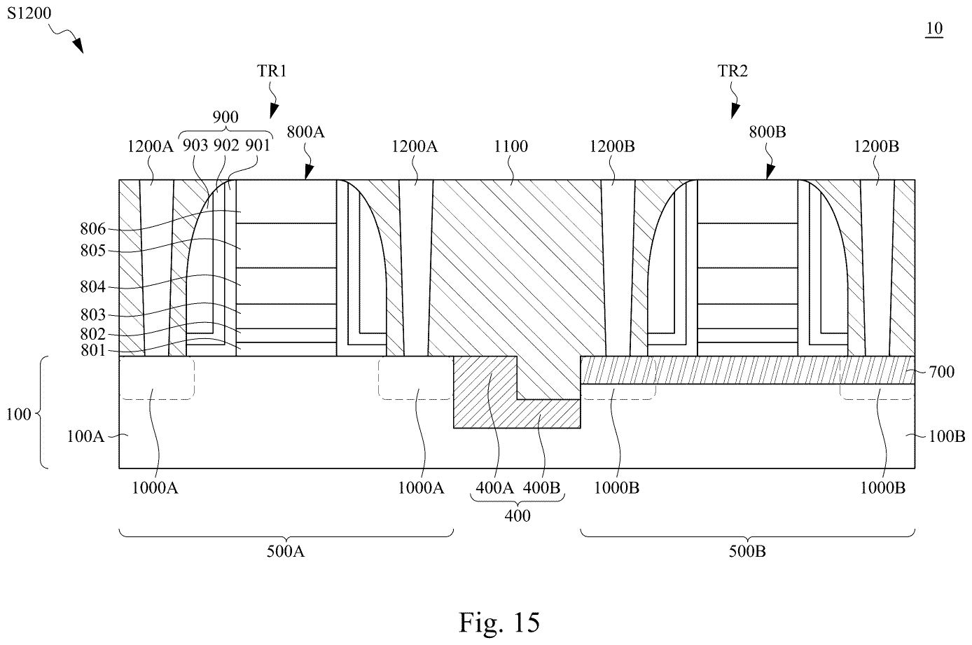

The method M10 proceeds to operation S1200 by forming an interlayer dielectric layer and source/drain electrodes. Referring to FIG. 15, an interlayer dielectric layer (ILD layer) 1100 is formed over the substrate layer 100, covering the source/drain regions 1000A and 1000B, and laterally surrounding the gate structures 800A and 800B. In some embodiments, the ILD layer 1100 is formed blanket over the substrate layer 100, followed by a planarization process (e.g., CMP process) to level the ILD layer 1100 with the gate structures 800A and 800B.

In some embodiments, the ILD layer 1100 may include multiple layers formed of a plurality of dielectric materials, such as silicon oxide, silicon nitride, silicon oxynitride, tetraethoxysilane (TEOS) oxide, phosphorus phosphosilicate glass (PSG), borophosphosilicate glass (BPSG), low-k dielectric materials and/or other applicable dielectric materials.

Then, the first source/drain electrodes 1200A and the second source/drain electrodes 1200B are formed in the ILD layer 1100 and electrically connected with the first source/drain region 1000A and the second source/drain region 1000B, respectively.

In some embodiments, the source/drain electrodes 1100A and 1100B may be formed by, for example, patterning the ILD layer 1100 to form openings in the ILD layer 1100 that expose the source/drain regions 1000A and 1000B, depositing a conductive material in the openings, and then performing a planarization process, such as CMP, to remove excess conductive material until the ILD layer 1100 is exposed. The first source/drain electrodes 1200A and the second source/drain electrodes 1200B may be deposited by using CVD, PECVD, ALD, PVD, LPCVD, FCVD, or other suitable deposition processes.

The first source/drain electrode 1200A and the second source/drain electrode 1200B may be made with conductive material. The first source/drain electrode 1200A and the second source/drain electrode 1200B may be configured to electrically connect to the first source/drain region 1000A and the second source/drain region 1000B, respectively. In some embodiments, the top surface of the first source/drain electrode 1200A or the second source/drain electrode 1200B may have a larger horizontal width than its bottom surface.

The combination of the elements in FIG. 15 can be referred as a semiconductor device 10. In some embodiments, the semiconductor device 10 is located in the memory peripheral circuit (MPC) 140 of the semiconductor memory 14, see FIG. 1.

To sum up, the present disclosure provides a method by performing an additional etching process to lower the top surface of the second substrate layer 100B, which will result in the following formed semiconductor layer 700 having a top surface that is substantially level with the top surface of the first substrate layer 100A. Accordingly, the top surface of the gate structure 800A overlying the first substrate layer 100A is at a substantially same vertical level as the top surface of the gate structure 800B overlying the semiconductor layer 700, which may be friendly for the subsequent processes such as the photo lithography process and the implant process, and thus the device performance may be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
forming a substrate layer and a pad layer over the substrate layer;
forming an isolation layer in the substrate layer and the pad layer, wherein the isolation layer separates the substrate layer and the pad layer into a first substrate layer and a first pad layer over the first substrate layer, and a second substrate layer and a second pad layer over the second substrate layer;
removing the second pad layer;
lowering a top surface of the second substrate layer; and
forming a semiconductor layer on the second substrate layer, wherein a top surface of the semiconductor layer is substantially level with a top surface of the first substrate layer.

2. The method of claim 1, wherein lowering the top surface of the second substrate layer includes performing an etching process using hydrogen chloride (HCl) and hydrogen (H₂).

3. The method of claim 1, wherein lowering the top surface of the second substrate layer is performed under a temperature lower than a melting point of a material of the second substrate layer.

4. The method of claim 3, wherein the temperature is in a range of approximately 930° C.±20°C.

5. The method of claim 1, wherein lowering the top surface of the second substrate layer is performed in a time period of approximately 5 seconds ±1 second.

6. The method of claim 1, wherein lowering the top surface of the second substrate layer comprises etching a vertical length of the second substrate layer by approximately 8 nm to approximately 10 nm from the top surface of the second substrate layer.

7. The method of claim 1, wherein forming the semiconductor layer on the second substrate layer is performed in a deposition rate in a range of approximately 0.1 Å/sec to approximately 0.8 Å/sec.

8. The method of claim 1, wherein forming the semiconductor layer on the second substrate layer is performed in a deposition temperature in a range of approximately 700° C.±50° C.

9. The method of claim 1, wherein forming the semiconductor layer on the second substrate layer is performed in a deposition pressure in a range of approximately 5 mTorr to approximately 30 mTorr.

10. The method of claim 1, wherein forming the semiconductor layer on the second substrate layer comprises a silicon (Si) precursor, wherein the Si precursor is dichlorosilane (DCS; SiH₂Cl₂) or silane (SiH₄), and a germanium (Ge) precursor, wherein the Ge precursor is germanium tetrafluoride (GeF₄).

11. A semiconductor device, comprising:
a substrate layer having a first region and a second region;
an isolation layer between the first region and the second region of the substrate layer;
a first transistor over the first region of the substrate layer and comprising:
a first portion of the substrate layer; and
a first gate structure over the first portion of the substrate layer; and
a second transistor over the second region of the substrate layer and comprising:
a second portion of the substrate layer;
a semiconductor layer over the second portion of the substrate layer, wherein a top surface of the semiconductor layer is substantially level with a top surface of the first portion of the substrate layer; and
a second gate structure over the semiconductor layer.

12. The semiconductor device of claim 11, wherein a top surface of the second portion of the substrate layer is lower than the top surface of the first portion of the substrate layer.

13. The semiconductor device of claim 11, wherein the semiconductor layer has a vertical length of approximately 8 nm to approximately 10 nm.

14. The semiconductor device of claim 11, wherein the isolation layer has a stepped top surface profile.

15. The semiconductor device of claim 14, wherein the isolation layer comprises a first portion closer to the first region of the substrate layer, wherein a top surface of the first portion of the isolation layer is substantially level with the top surface of the first portion of the substrate layer.

16. The semiconductor device of claim 15, wherein the isolation layer further comprises a second portion closer to the second region of the substrate layer, wherein a top surface of the second portion of the isolation layer is at a lower vertical level than the top surface of the second portion of the substrate layer.

17. The semiconductor device of claim 11, wherein the semiconductor layer and the first portion of the substrate layer are made of different semiconductor materials.

18. The semiconductor device of claim 17, wherein the semiconductor layer is made of silicon-germanium (SiGe) and the substrate layer is made of silicon (Si).

19. The semiconductor device of claim 11, wherein the first transistor comprises first source/drain regions in the first portion of the substrate layer and on opposite sides of the first gate structure, and the second transistor comprises second source/drain regions in the semiconductor layer and on opposite sides of the second gate structure, wherein the first source/drain regions include N-type dopants and the second source/drain regions include P-type dopants.

20. The semiconductor device of claim 19, wherein the second source/drain regions further extend to the second portion of the substrate layer.
